(19) United States
(12) Patent Application Publication
(10) Pub. No.: US 2026/0255672 A1
(43) Pub. Date: Aug. 27, 2026

(54) FIELD-EFFECT TRANSISTOR AND MANUFACTURING METHOD THEREOF

(71) Applicant: INSTITUTE OF MICROELECTRONICS, CHINESE ACADEMY OF SCIENCES, Beijing (CN)

(72) Inventors: Lei Cao, Beijing (CN); Huaxiang Yin, Beijing (CN); Qingzhu Zhang, Beijing (CN); Jiaxin Yao, Beijing (CN); Yadong Zhang, Beijing (CN)

(21) Appl. No.: 19/337,303

(22) Filed: Sep. 23, 2025

(30) Foreign Application Priority Data
Feb. 21, 2025 (CN) 202510195867.5

(51) Int. Cl. H10D 84/85; H10D 84/01

(52) U.S. Cl. CPC H10D 84/856; H10D 84/0167; H10D 84/017; H10D 84/0177; H10D 84/0186; H10D 84/851

(57) ABSTRACT

A field-effect transistor and a method for manufacturing a field-effect transistor are provided. The field-effect transistor includes: a bottom dielectric isolation layer formed at a bottom of the field-effect transistor by bonding a first bonding layer and a second bonding layer; a top source, a top drain, a top channel structure, a bottom source, a bottom drain and a bottom channel structure provided on a side of the bottom dielectric isolation layer, where an intermediate dielectric layer is between a top channel structure and a bottom channel structure, the top channel structure and the bottom channel structure include a stack formed by a plurality of nanosheets, and the gate surrounds the nanosheets.

### CROSS REFERENCE OF RELATED APPLICATION

This application claims the priority to Chinese Patent Application No. 202510195867.5, titled “FIELD-EFFECT TRANSISTOR AND MANUFACTURING METHOD THEREOF,” filed on Feb. 21, 2025 with the China National Intellectual Property Administration (CNIPA), which is incorporated herein by reference in its entirety.

### FIELD

The present disclosure relates to the field of semiconductors, and in particular to a complementary field-effect transistor and a manufacturing method thereof.

### BACKGROUND

With the development of semiconductor technology, the feature size of integrated circuits continues to shrink. Traditional three-gate or double-gate fin field-effect transistors (FinFETs) are subjected to limitations below 3-nanometer (nm) nodes, and nanosheet-gate all round fin field-effect transistors (Nanosheet-GAAFETs) that can alleviate the 3-nm node limitation have been developed. Furthermore, complementary field-effect transistors (CFET), by breaking a 1-nm node limitation, have received extensive attention and research.

Current field-effect transistors with short channels have a parasitic leakage problem related to bottom substrate.

### SUMMARY

In view of the above problem, the present disclosure aims to provide a field-effect transistor and a manufacturing method thereof, which can avoid a parasitic leakage problem existing in field-effect transistors with short channels and improve the performance of complementary field-effect transistors.

The present disclosure provides a field-effect transistor, including:
a bottom dielectric isolation layer, where the bottom dielectric isolation layer includes a first bonding layer and a second bonding layer;
a top source, a top drain, a top channel structure, a bottom source, a bottom drain and a bottom channel structure provided on the bottom dielectric isolation layer, where the top channel structure and the bottom channel structure overlap in a direction perpendicular to a plane where the bottom dielectric isolation layer is located, the top channel structure and the bottom channel structure are isolated by an intermediate dielectric layer, the top channel structure is located between the top source and the top drain, the bottom channel structure is located between the bottom source and the bottom drain, and the top channel structure and the bottom channel structure include a stack formed by a plurality of nanosheets; and
a gate, where the gate surrounds the nanosheets.

In an embodiment, a thickness of the first bonding layer is greater than a thickness of the second bonding layer, and the thickness of the first bonding layer is greater than a thickness of the intermediate dielectric layer.

In an embodiment, the thickness of the first bonding layer and the thickness of the second bonding layer range from 1 nm to 1000 nm.

In an embodiment, the first substrate is a silicon substrate, a germanium substrate or a germanium-silicon substrate, and a semiconductor-on-insulator substrate is a silicon-on-insulator substrate, a germanium-on-insulator substrate or a germanium-silicon-on-insulator substrate.

In an embodiment, the first bonding layer or the second bonding layer is made of one or more of SiO₂, SiNₓ, SiNO, SiCO, SiCNO and SiCN.

In an embodiment, a thickness of the intermediate dielectric layer ranges from 1 nm to 100 nm.

In an embodiment, conductivity types of the top channel structure and the bottom channel structure are N-type and P-type respectively; or P-type and N-type respectively.

In an embodiment, the intermediate dielectric layer includes a first portion located at a center and a second portion located at both sides of the first portion, where the second portion extends along both sides of a surface of the first portion in a direction perpendicular to a surface of the bottom dielectric isolation layer, and a thickness of the second portion is greater than a thickness of the first portion.

In an embodiment, a contact interface is included between the first portion and the second portion.

The present disclosure provides a method for manufacturing a field-effect transistor, including:
providing a first substrate, and forming a first bonding layer at the first substrate;
providing a semiconductor-on-insulator substrate, where the semiconductor-on-insulator substrate includes a bottom semiconductor substrate, a buried oxide layer and a top semiconductor substrate that are stacked in layers, a first stacked structure and a second bonding layer are formed at the semiconductor-on-insulator substrate, and the first stacked structure is obtained by alternately stacking a plurality of first semiconductor layers and a plurality of second semiconductor layers;
bonding the first substrate and the semiconductor-on-insulator substrate in a direction where the second bonding layer faces the first bonding layer;
forming a second stacked structure at the bottom semiconductor substrate, where the second stacked structure is obtained by alternately stacking a plurality of first semiconductor layers and a plurality of second semiconductor layers; and
processing the first stacked structure and the second stacked structure to form a field-effect transistor.

In an embodiment, processing the first stacked structure and the second stacked structure to form the field-effect transistor includes:
processing the first stacked structure and the second stacked structure to form a nanosheet stacked structure, where the nanosheet stacked structure includes a bottom structure located below the buried oxide layer and a top structure located above the buried oxide layer;
forming a bottom source and a bottom drain at both sides of the bottom structure, and forming a top source and a top drain at both sides of the top structure; and
removing the second semiconductor layers to form a plurality of to-be-filled gaps, and filling the plurality of to-be-filled gaps with a gate, where the plurality of first semiconductor layers surrounded by the gate constitute a channel structure, the channel structure includes a top channel structure and a bottom channel structure, and the top channel structure and the bottom channel structure are separated by the buried oxide layer.

In an embodiment, before forming the bottom source and the bottom drain at both sides of the bottom structure, the method further includes:
selectively etching the second semiconductor layers located in the top structure and the bottom structure to form a concave structure; and
forming an inner spacer in the concave structure.

In an embodiment, forming the inner spacer in the concave structure includes:
forming an inner spacer along both sides of a surface of the buried oxide layer in a direction perpendicular to a surface of the bottom dielectric isolation layer, where the inner spacer and the buried oxide layer constitute an intermediate dielectric layer.

In an embodiment, after forming the bottom source and the bottom drain at both sides of the bottom structure and before forming the top source and the top drain at both sides of the top structure, the method further includes:
forming a first dielectric layer between the bottom source and the bottom drain at both sides of the bottom structure and between the top source and the top drain at both sides of the top structure.

In an embodiment, before filling the plurality of to-be-filled gaps with the gate, the method further includes:
forming a second work function layer in the plurality of to-be-filled gaps of the bottom structure; and
forming a first work function layer in the plurality of to-be-filled gaps of the top structure.

In an embodiment, before forming the second stacked structure at the bottom semiconductor substrate, the method further includes:
thinning a thickness of the bottom semiconductor substrate to a thickness of the first semiconductor layers or a thickness of the second semiconductor layers.

### BRIEF DESCRIPTION OF THE DRAWINGS

In order to more clearly illustrate technical solutions in embodiments of the present disclosure, the drawings required for the description of the embodiments would be briefly introduced below. The drawings described below are some embodiments of the present disclosure. For those of ordinary skill in the art, other drawings may be obtained based on these drawings without any creative effort.

FIG. 1 shows a schematic diagram of a three-dimensional structure of a field-effect transistor according to an embodiment of the present disclosure;

FIG. 2 and FIG. 3 are schematic cross-sectional structural diagrams of the field-effect transistor shown in FIG. 1 taken along a XX direction and a YY direction according to an embodiment of the present disclosure;

FIG. 4 is a schematic flowchart of a method for manufacturing a field-effect transistor according to an embodiment of the present disclosure; and

FIG. 5 to FIG. 20B show schematic structural diagrams of manufacturing a field-effect transistor with the manufacturing method according to an embodiment of the present disclosure.

### DETAILED DESCRIPTION

In order to enable those skilled in the art to better understand solutions of the present disclosure, technical solutions in the embodiments of the present disclosure would be clearly and completely described below in conjunction with drawings in the embodiments of the present disclosure. The described embodiments are only part of the embodiments of the present disclosure, not all of the embodiments. Based on the embodiments in the present disclosure, any other embodiments obtained by those of ordinary skill in the art without creative work fall within the scope of protection of the present disclosure.

Although many specific details are set forth in the following description to facilitate a full understanding of the present disclosure, the present disclosure may be implemented in other ways different from those described herein, and those skilled in the art may make similar generalizations without violating the connotation of the present disclosure. Therefore, the present disclosure is not limited to the specific embodiments disclosed Below.

Secondly, the present disclosure is described in detail with reference to the schematic diagram. When describing the embodiments of the present disclosure in detail, to facilitate description, the cross-sectional diagrams showing the device structure will not be partially enlarged according to the general scale, and the schematic diagrams are only examples, which should not limit the protection scope of the present disclosure. In addition, in actual production, three-dimensional dimensions of length, width and depth should be included.

Current field-effect transistors with short channels suffer from substrate parasitic leakage. The parasitic leakage of the field-effect transistors with short channels may be suppressed by forming heavily doped wells in the substrate during a procedure of manufacturing the field-effect transistors. However, the heavily doped well cannot completely avoid parasitic leakage.

In addition, in the procedure of manufacturing the field-effect transistor, it is necessary to form an intermediate isolation layer between a top channel structure and a bottom channel structure. The intermediate isolation layer serves as an insulating dielectric to separate the top channel structure and the bottom channel structure. The formation procedure of the intermediate isolation layer is: a stacked structure of alternately stacked silicon germanium (SiGe) layers and silicon (Si) layers with different germanium (Ge) contents is firstly formed, where a SiGe layer located in a middle area of the stacked structure has the highest germanium content; a SiGe layer with a high Ge content is selectively removed to form a gap; and then the gap is filled with some isolation dielectrics to form the intermediate isolation layer. However, this method has extremely high requirements on material selectivity and isolation dielectric filling, and has relatively high process complexity.

Therefore, there is a need to reduce the process complexity of field-effect transistors and improve their performance.

Based on this, the present disclosure provides a field-effect transistor. The field-effect transistor includes a bottom dielectric isolation layer, where the bottom dielectric isolation layer includes a first bonding layer and a second bonding layer. That is, the bottom dielectric isolation layer is formed at a bottom of the field-effect transistor by bonding the first bonding layer and the second bonding layer, to provide an insulating dielectric under a subsequently formed channel structure. The insulating dielectric may avoid a substrate parasitic leakage problem existing in a field-effect transistor with short channel. The field-effect transistor further includes a top source, a top drain, a top channel structure, a bottom source, a bottom drain and a bottom channel structure provided at a side of the bottom dielectric isolation layer, where the top channel structure and the bottom channel structure are isolated by an intermediate dielectric layer, the top channel structure and the bottom channel structure overlap in a direction perpendicular to a plane where the bottom dielectric isolation layer is located, the top channel structure is located between the top source and the top drain, the bottom channel structure is located between the bottom source and the bottom drain, the top channel structure and the bottom channel structure include a stack formed by a plurality of nanosheets, and the gate surrounds the nanosheets. That is, the buried oxide layer may be used as an insulating dielectric between the top channel structure and the bottom channel structure, which greatly reduces the process complexity of forming an insulating layer between the top channel structure and the bottom channel structure. That is, the insulating dielectric located at the bottom of the channel structure is formed by bonding the first bonding layer and the second bonding layer, and the insulating dielectric between the top channel structure and the bottom channel structure is formed by the intermediate dielectric layer, which not only avoids the substrate parasitic leakage problem existing in the field-effect transistor with short channel, but also can reduce the process complexity of forming the insulating dielectric between the top channel structure and the bottom channel structure, and finally improves the performance of the manufactured field-effect transistor.

In order to better understand technical solutions and technical effects of the present disclosure, specific embodiments would be described in detail below with reference to the accompanying drawings.

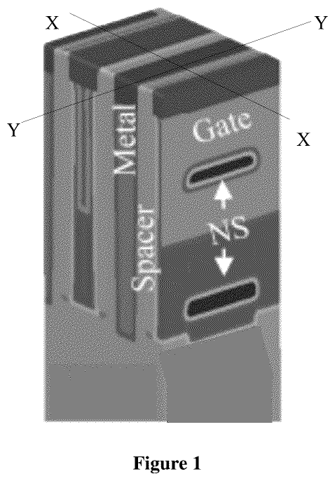

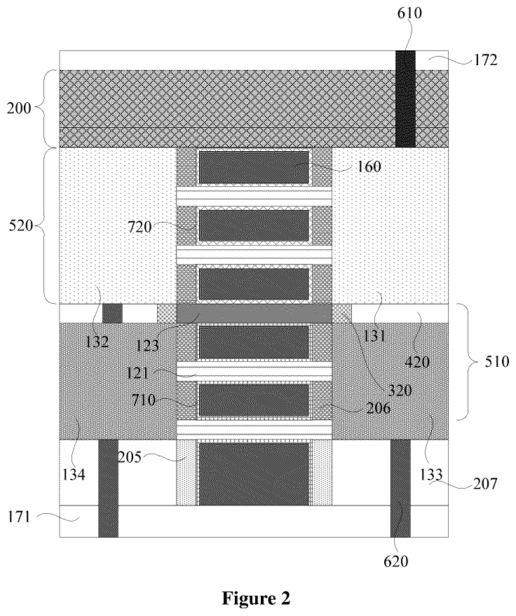

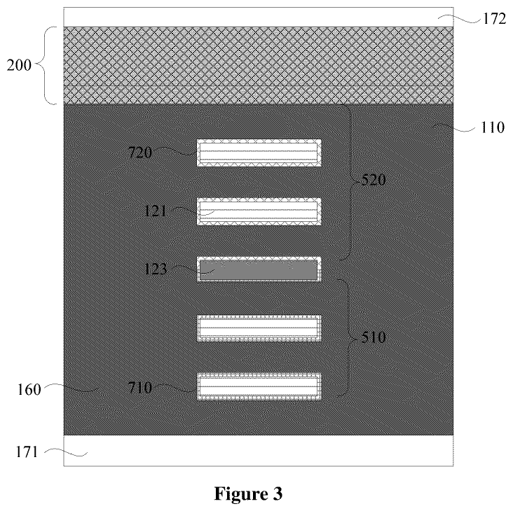

FIG. 1 is a schematic diagram of a three-dimensional structure of a field-effect transistor according to an embodiment of the present disclosure. FIG. 2 and FIG. 3 are obtained by cross-sections of FIG. 1 taken along a XX direction and a YY direction respectively. The field-effect transistor provided by an embodiment of the present disclosure includes a bottom dielectric isolation layer (BDI) 200, a top source 133, a top drain 134, a top channel structure, a bottom source 131, a bottom drain 132, a bottom channel structure and a gate 160.

In an embodiment of the present disclosure, the bottom dielectric isolation layer 200 includes a first bonding layer 210 and a second bonding layer 220. The bottom dielectric isolation layer 200 is constituted by the first bonding layer 210 and the second bonding layer 220, which have already been used for bonding the first substrate 110 and a semiconductor-on-insulator substrate 310.

In an embodiment, the first bonding layer 210 is formed at the first substrate 110, and a first stacked structure and the second bonding layer 220 are formed at the semiconductor-on-insulator substrate 310, where the first stacked structure is obtained by alternately stacking a plurality of first semiconductor layers 121 and a plurality of second semiconductor layers 122. The semiconductor-on-insulator substrate 310 includes a bottom semiconductor substrate 311, a buried oxide layer 123 and a top semiconductor substrate 312 that are stacked in layers. The first substrate 110 and the semiconductor-on-insulator substrate 310 are bonded in a direction where the second bonding layer 220 faces the first bonding layer 210, and the first bonding layer 210 and the second bonding layer 220 are in direct contact to form the bottom dielectric isolation layer 200. After bonding, the bottom dielectric isolation layer 200 is formed as a bottom substrate of the field-effect transistor, thereby overcoming a parasitic leakage problem of a ground plane heavily-doped well (GP Well) in a traditional bulk silicon field-effect transistor.

As a possible implementation, a thickness of the first bonding layer 210 is greater than a thickness of the second bonding layer 220, that is, a thicker first bonding layer 210 and a thinner second bonding layer 220 are bonded to construct the bottom dielectric isolation layer 200.

As a possible implementation, the thickness of the first bonding layer 210 and the thickness of the second bonding layer 220 range from 1 nm to 1000 nm, that is, a thickness of the bottom dielectric isolation layer 200 ranges from 1 nm to 1000 nm, so that the parasitic leakage problem is controlled by controlling a thickness of the bottom dielectric isolation layer 200.

As a possible implementation, the first bonding layer 210 or the second bonding layer 220 is made of insulating material, so as to suppress parasitic leakage. The first bonding layer 210 or the second bonding layer 220 is made of one or more of SiO₂, SiNₓ, SiNO, SiCO, SiCNO and SiCN.

As a possible implementation, the first substrate 110 is a silicon substrate, a germanium substrate or a germanium-silicon substrate, and the semiconductor-on-insulator substrate 310 is a silicon-on-insulator substrate, a germanium-on-insulator substrate or a germanium-silicon-on-insulator substrate. That is, the bottom semiconductor substrate 311 and the top semiconductor substrate 312 are made of silicon, germanium or germanium-silicon.

The top source 133, the top drain 134, the top channel structure, the bottom source 131, the bottom drain 132 and the bottom channel structure are provided at a side of the bottom dielectric isolation layer 200. The top channel structure and the bottom channel structure include a stack formed by a plurality of nanosheets, and the stack formed by nanosheets is obtained by removing the second semiconductor layers 122 from the plurality of first semiconductor layers 121 and the plurality of second semiconductor layers 122 that are alternately stacked. The top channel structure and the bottom channel structure overlap in a direction perpendicular to a plane where the bottom dielectric isolation layer 200 is located.

In an embodiment of the present disclosure, conductivity types of the top channel structure and the bottom channel structure may be different, thereby forming a complementary field-effect transistor. For example, the conductivity types of the top channel structure and the bottom channel structure are N-type and P-type respectively; or P-type and N-type respectively.

In an embodiment, for different device types, a material of the first semiconductor layers 121 and a material of the second semiconductor layers 122 may be the same. For example, for a P-type semiconductor device and an N-type semiconductor device, the first semiconductor layers 121 may be made of silicon germanium, and the second semiconductor layers 122 may be made of silicon or germanium. For different device types, the material of the first semiconductor layers 121 and the material of the second semiconductor layers 122 may be different. For example, for a P-type semiconductor device, the first semiconductor layers 121 may be made of silicon, and the second semiconductor layers 122 may be made of silicon germanium. For an N-type semiconductor device, the material of the first semiconductor layers 121 may be made of silicon germanium, and the second semiconductor layers 122 may be made of silicon.

As an example, the complementary field-effect transistor includes a top N-type field-effect transistor and a bottom P-type field-effect transistor. The material of the first semiconductor layers 121 of the top N-type field-effect transistor and the material of the first semiconductor layers 121 of the bottom P-type field-effect transistor are the same, and the material of the second semiconductor layers 122 of the top N-type field-effect transistor and the material of the second semiconductor layers 122 of the bottom P-type field-effect transistor are also the same. The material of the first semiconductor layers 121 may be silicon germanium, where the proportion of germanium is 30%, and the material of the second semiconductor layers 122 may be silicon.

In a direction parallel to a surface of the bottom dielectric isolation layer 200, the top channel structure is located between the top source 133 and the top drain 134, and the bottom channel structure is located between the bottom source 131 and the bottom drain 132.

An intermediate dielectric layer is provided between the top channel structure and the bottom channel structure in a direction perpendicular to the plane where the bottom dielectric isolation layer 200 is located, that is, the intermediate dielectric layer isolates the top channel structure from the bottom channel structure, thereby forming a separation between upper and lower transistors of the field-effect transistor.

As a possible implementation, the thickness of the first bonding layer 210 is greater than a thickness of the intermediate dielectric layer.

In an embodiment of the present disclosure, the intermediate dielectric layer includes a first portion located at a center and a second portion located at both sides of the first portion, where the second portion extends along both sides of a surface of the first portion in a direction perpendicular to the surface of the bottom dielectric isolation layer 200, and a thickness of the second portion is greater than a thickness of the first portion. In other words, the intermediate dielectric layer has an H-shaped structure.

In an embodiment, a contact interface is included between the first portion and the second portion, that is, the first part and the second part are not formed simultaneously, and the first part and the second part are in contact with each other through the contact interface. The first portion is the buried oxide layer 123, and the second portion is an inner spacer 206 in contact with the buried oxide layer 123.

In an embodiment, the buried oxide layer 123 is made of insulating material, and thickness of the buried oxide layer 123 ranges from 1 nm to 100 nm. The material of the buried oxide layer 123 may be the same as or different from a material of the inner spacer 206.

As a possible implementation, in a direction perpendicular to the plane where the bottom dielectric isolation layer 200 is located, the top source 133 overlaps with the bottom source 131, and the top drain 134 overlaps with the bottom drain 132.

In an embodiment of the present disclosure, there is a gap between the plurality of nanosheets in the top channel structure and the bottom channel structure, and the gap is filled with the gate 160, that is, the gate 160 surrounds the nanosheets to form a gate-all-around structure.

In an embodiment of the present disclosure, the inner spacer 206 is provided between adjacent nanosheets, and the inner spacer 206 may be made of one or more of silicon oxide, silicon nitride, aluminum oxide, silicon oxynitride, silicon oxycarbide, boron nitride and low-κ materials.

An interface layer, a high-κ dielectric layer and a work function layer may be further provided between the gate 160 and the nanosheets, that is, the interface layer is provided around the nanosheets, the high-κ dielectric layer is provided around the interface layer, and the work function layer is provided around the high-κ dielectric layer. The interface layer may be made of silicon oxide. The high-κ dielectric layer may be made of one or a combination of any of HfO₂, HfSiOₓ, HfON, HfSiON, HfAlOₓ, HfLaOₓ, Al₂O₃, ZrO₂, ZrSiOₓ, Ta₂O₅ or La₂O₃.

Field-effect transistors of different device types may be implemented using different types of work function layers. The different types of work function layers include a first-type work function layer 710 and a second-type work function layer 720. The first-type work function layer 710 is one of a P-type work function layer (P-WFL) and an N-type work function layer (N-WFL), and the second-type work function layer 720 is the other of the P-type work function layer and the N-type work function layer.

As an example, a work function layer of the top N-type field-effect transistor is the first-type work function layer 710, and a work function layer of the bottom P-type field-effect transistor is the second-type work function layer 720. The first-type work function layer 710 is the N-type work function layer, and the second-type work function layer 720 is the P-type work function layer.

In an embodiment of the present disclosure, the bottom dielectric isolation layer 200 includes a back contact 610. The back contact 610 is connected to the bottom source 131 or the bottom drain 132, so as to realize electrical extraction of the field-effect transistor. The back contact 610 is made of metal material. Since the bottom dielectric isolation layer 200 may realize isolation between adjacent fins, it is not necessary to provide shallow trench isolation in the field-effect transistor, thereby simplifying a process flow.

In an embodiment of the present disclosure, the semiconductor device further includes second spacers 205, isolation layers 207, a top dielectric layer 171, a bottom dielectric layer 172 and a contact electrode 620. The second spacers 205 are provided at a side of the top channel structure away from the bottom dielectric isolation layer 200, and the gate 160 is provided between the second spacers 205. The isolation layers 207 are provided at a side of the bottom source 131 or the bottom drain 132 away from the bottom dielectric isolation layer 200, and the second spacers 205 and the gate 160 are provided between the isolation layers 207. The top dielectric layer 171 covers the isolation layers 207, the second spacers 205 and the gate 160, and the contact electrode 620 is provided in the top dielectric layer 171 and the isolation layers 207, where the contact electrode 620 is used to implement electric extraction on the bottom source 131 or the bottom drain 132. The bottom dielectric layer 172 covers a surface of the bottom dielectric isolation layer 200 away from the bottom channel structure, and the back contact 610 is provided in the bottom dielectric layer 172.

It can be seen that the field-effect transistor provided by the present disclosure includes: a bottom dielectric isolation layer, where the bottom dielectric isolation layer is constituted by a first bonding layer and a second bonding layer, which have already been used for bonding a first substrate and a semiconductor-on-insulator substrate. That is, the bottom dielectric isolation layer is formed at a bottom of the field-effect transistor by the bonding via the first bonding layer and the second bonding layer, to provide an insulating dielectric under a subsequently formed channel structure. The insulating dielectric may avoid a parasitic leakage problem existing in field-effect transistors with short channels. The semiconductor-on-insulator substrate includes a buried oxide layer, that is, the buried oxide layer may be used as an insulating dielectric between the top channel structure and the bottom channel structure, which greatly reduces the process complexity of forming an insulating layer between the top channel structure and the bottom channel structure. That is, the insulating dielectric located at the bottom of the channel structure is formed by bonding the first bonding layer and the second bonding layer, and the intermediate dielectric layer between the top channel structure and the bottom channel structure is formed by including the buried oxide layer in the semiconductor-on-insulator substrate, which not only avoids the substrate parasitic leakage under the short channel existing in the field-effect transistor, but also can reduce the process complexity of forming the insulating dielectric between the top channel structure and the bottom channel structure, and finally improves the performance of the manufactured field-effect transistor.

Based on the field-effect transistor provided by the above embodiments, an embodiment of the present disclosure further provides a method for manufacturing a field-effect transistor, and its working principle is described in detail below in conjunction with the accompanying drawings.

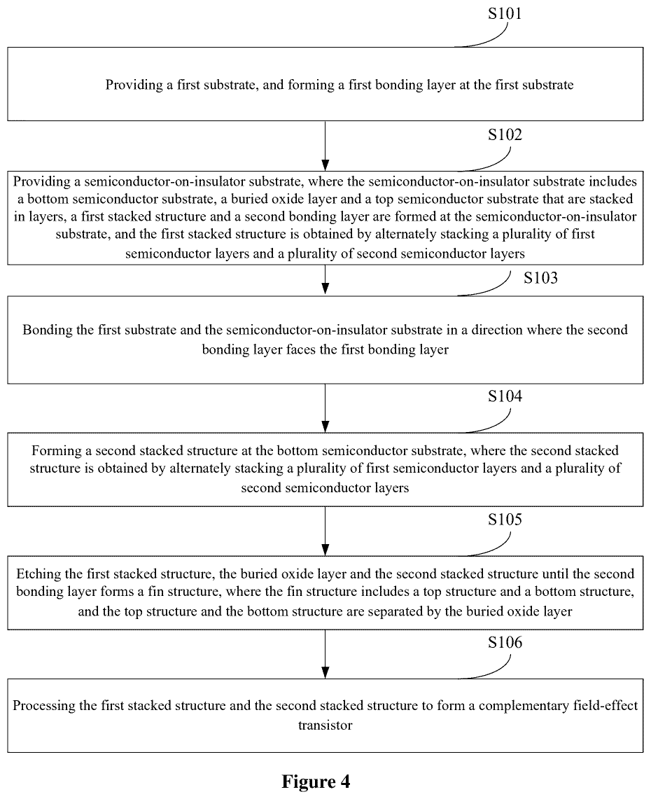

Reference is made to FIG. 4, which is a schematic flowchart of a method for manufacturing a field-effect transistor according to an embodiment of the present disclosure.

The method for manufacturing a field-effect transistor provided by the embodiment of the present disclosure includes the following steps.

In S101, a first substrate is provided, and a first bonding layer is formed at the first substrate.

S102: a semiconductor-on-insulator substrate is provided, where the semiconductor-on-insulator substrate includes a bottom semiconductor substrate, a buried oxide layer and a top semiconductor substrate that are stacked in layers, a first stacked structure and a second bonding layer are formed at the semiconductor-on-insulator substrate, and the first stacked structure is obtained by alternately stacking a plurality of first semiconductor layers and a plurality of second semiconductor layers.

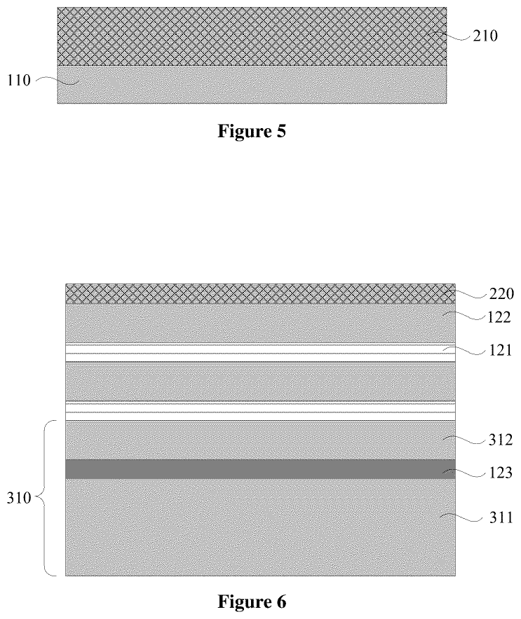

In an embodiment of the present disclosure, a first substrate 110 and a semiconductor-on-insulator substrate 310 are provided, and a first bonding layer 210 is formed at the first substrate 110, as shown in FIG. 5. A first stacked structure and a second bonding layer 220 are formed at the semiconductor-on-insulator substrate 310, as shown in FIG. 6, where the first stacked structure is obtained by alternately stacking a plurality of first semiconductor layers 121 and a plurality of second semiconductor layers 122. The semiconductor-on-insulator substrate 310 includes a bottom semiconductor substrate 311, a buried oxide layer 123, and a top semiconductor substrate 312 that are stacked in layers.

As a possible implementation, the first substrate 110 is a silicon substrate, a germanium substrate or a silicon germanium substrate, and the semiconductor-on-insulator substrate 310 is a silicon-on-insulator substrate, a germanium-on-insulator substrate or a silicon-germanium-on-insulator substrate. That is, a material of the bottom semiconductor substrate 311 and the top semiconductor substrate 312 is silicon, germanium or silicon germanium.

In S103, the first substrate is bonded to the semiconductor-on-insulator substrate in a direction where the second bonding layer faces the first bonding layer.

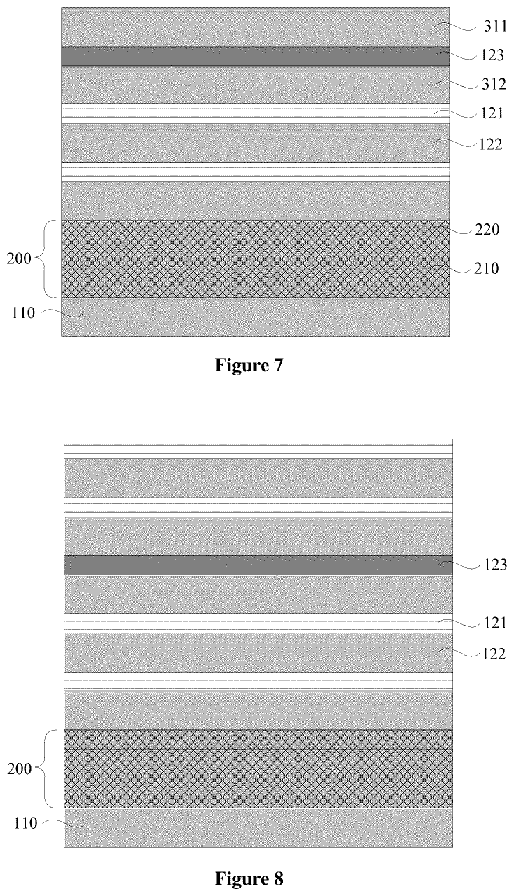

In an embodiment of the present disclosure, the first substrate 110 and the semiconductor-on-insulator substrate 310 are bonded in a direction where the second bonding layer 220 faces the first bonding layer 210, the first bonding layer 210 and the second bonding layer 220 are in direct contact to form a bottom dielectric isolation layer 200. Referring to FIG. 7, the bottom dielectric isolation layer 200 is formed as a bottom substrate of the field-effect transistor, thereby overcoming a parasitic leakage problem of a ground plane heavily-doped well (GP Well) in a traditional bulk silicon field-effect transistor.

As a possible implementation, a thickness of the first bonding layer 210 is greater than a thickness of the second bonding layer 220, that is, a thicker first bonding layer 210 and a thinner second bonding layer 220 are bonded to construct the bottom dielectric isolation layer 200.

As a possible implementation, the thickness of the first bonding layer 210 and the thickness of the second bonding layer 220 range from 1 nm to 1000 nm, that is, a thickness of the bottom dielectric isolation layer 200 ranges from 1 nm to 1000 nm, so that a substrate parasitic leakage is controlled by controlling a thickness of the bottom dielectric isolation layer 200.

As a possible implementation, the first bonding layer 210 or the second bonding layer 220 is made of insulating material, so as to suppress parasitic leakage. The first bonding layer 210 or the second bonding layer 220 is made of one or more of SiO₂, SiNₓ, SiNO, SiCO, SiCNO and SiCN.

In an embodiment of the present disclosure, the bottom semiconductor substrate 311 is ground using a chemical mechanical polishing (CMP) process, and then a high-temperature sacrificial oxidation and oxide layer removal method is introduced until a comprehensive thickness of the bottom semiconductor substrate 311 is thinned to be equal to a thickness of the first semiconductor layers 121 or a thickness of the second semiconductor layers 122.

As an example, the thickness of the bottom semiconductor substrate 311 is thinned to be equal to the thickness of the second semiconductor layers 122, as shown in FIG. 7.

In S104, a second stacked structure is formed at the bottom semiconductor substrate, where the second stacked structure is obtained by alternately stacking a plurality of first semiconductor layers and a plurality of second semiconductor layers.

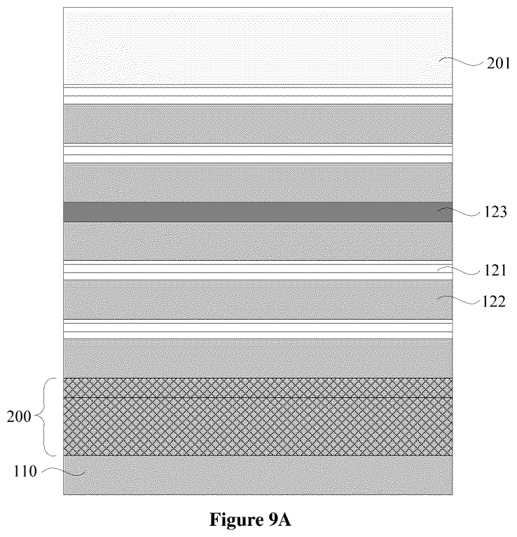

In an embodiment of the present disclosure, after bonding the first substrate 110 and the semiconductor-on-insulator substrate 310 and thinning the bottom semiconductor substrate 311, the second stacked structure may be formed at the bottom semiconductor substrate 311, as shown in FIG. 8, where the second stacked structure is obtained by alternately stacking a plurality of first semiconductor layers 121 and a plurality of second semiconductor layers 122. The second stacked structure includes the bottom semiconductor substrate 311.

In an embodiment, for different device types, a material of the first semiconductor layers 121 and a material of the second semiconductor layers 122 may be the same. For example, the first semiconductor layers 121 may be made of silicon germanium, and the second semiconductor layers 122 may be made of silicon or germanium. For different device types, the material of the first semiconductor layers 121 and the material of the second semiconductor layers 122 may be different. For example, for a P-type semiconductor device, the first semiconductor layers 121 may be made of silicon, and the second semiconductor layers 122 may be made of silicon germanium. For an N-type semiconductor device, the first semiconductor layers 121 may be made of silicon germanium, and the second semiconductor layers 122 may be made of silicon.

A buried oxide layer 123 is provided between the first stacked structure and the second stacked structure in a direction perpendicular to a plane where the bottom dielectric isolation layer 200 is located, that is, the first stacked structure and the second stacked structure are separated by the buried oxide layer 123, thereby forming a separation between upper and lower transistors of the field-effect transistor.

In an embodiment, the buried oxide layer 123 is made of insulating material, and thickness of the buried oxide layer 123 ranges from 1 nm to 100 nm.

In S105, the first stacked structure, the buried oxide layer and the second stacked structure are etched until the second bonding layer forms a fin structure, where the fin structure includes a top structure and a bottom structure, and the top structure and the bottom structure are separated by the buried oxide layer.

In an embodiment of the present disclosure, the first stacked structure, the buried oxide layer 123 and the second stacked structure may be etched until the second bonding layer 220 forms the fin structure, where the fin structure includes the top structure and the bottom structure, and the top structure and the bottom structure are separated by the buried oxide layer 123. A process flow of forming the fin structure is specifically described below.

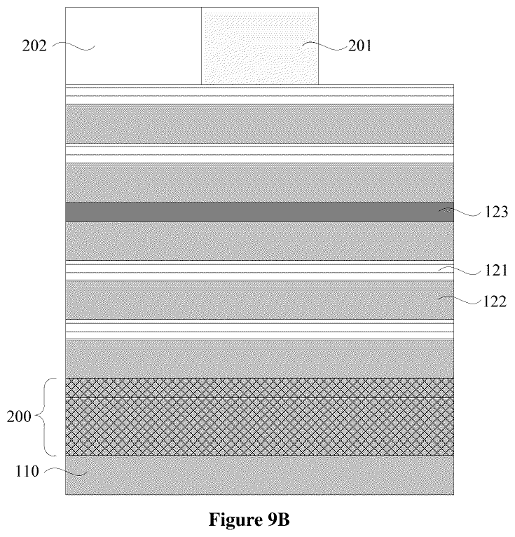

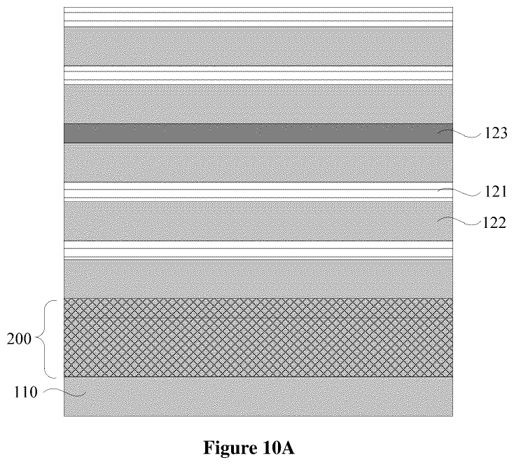

In S1051, a spacer transfer process is performed, as shown in FIG. 9A and FIG. 9B. FIG. 9A and FIG. 9B are obtained by cross-sections of FIG. 1 taken in a XX direction and a YY direction respectively.

In an embodiment of the present disclosure, a self-aligned spacer transfer process is used to form a first spacer 201. The first spacer 201 is made of silicon nitride, and a specific formation procedure is as follows. A sacrificial layer 202 is covered on the second stacked structure, where the sacrificial layer 202 may be made of polycrystalline silicon or amorphous silicon. Part of the sacrificial layer 202 is removed by performing patterned etching through photolithography, silicon nitride material is deposited, anisotropic etching is then used to remove the remaining sacrificial layer 202, and only the first spacer 201 is retained on the stacked structure. The first spacer 201 acts as a hard mask in the subsequent photolithography for forming a fin.

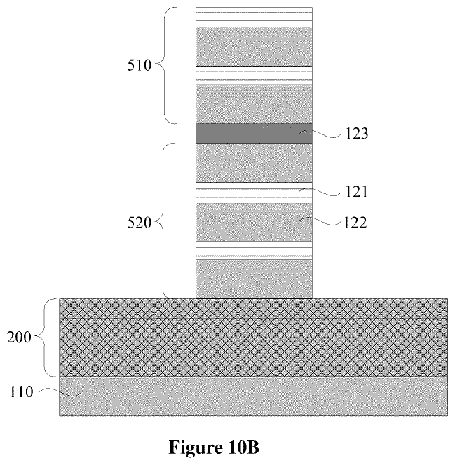

In S1052, the fin structure is formed, as shown in FIG. 10A and FIG. 10B. FIG. 10A and FIG. 10B are obtained by cross-sections of FIG. 1 taken in a XX direction and a YY direction respectively.

In an embodiment of the present disclosure, the first stacked structure, the buried oxide layer 123 and the second stacked structure can be etched by an etching process to form a plurality of periodically distributed fins, as shown in FIG. 10A and FIG. 10B. The first spacer 201 is used as a mask for etching to form a fin with a stacked structure. The fin structure includes a top structure 510 and a bottom structure 520, and the top structure 510 and the bottom structure 520 are separated by the buried oxide layer 123. The top structure 510 and the bottom structure 520 are channel regions, and a fin as shown in FIG. 10B is formed. The etching process may be dry etching or wet etching, and reactive ion etching may be used in an embodiment. The fin structure would be used to form a nanosheet of the field-effect transistor. Although FIG. 10B shows one fin, it should be understood that any suitable number and form of fins may be used in practical applications.

In practical applications, after the fin structure is formed, the first spacer 201 may be removed.

Since the bottom dielectric isolation layer 200 may realize isolation between adjacent fins, there is no need to provide shallow trench isolation in the field-effect transistor, thereby simplifying a process flow.

In S106, the first stacked structure and the second stacked structure are processed to form the field-effect transistor.

In an embodiment of the present disclosure, after the first stacked structure and the second stacked structure are formed, the first stacked structure and the second stacked structure may be further processed to finally form the field-effect transistor.

In an embodiment, the first stacked structure and the second stacked structure may be processed to form a nanosheet stacked structure, where the nanosheet stacked structure includes the bottom structure 520 located below the buried oxide layer 123 and the top structure 510 located above the buried oxide layer 123. A specific process is specifically described in the following.

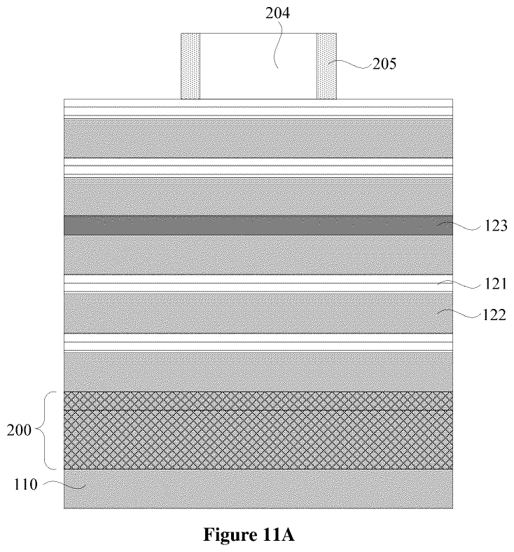

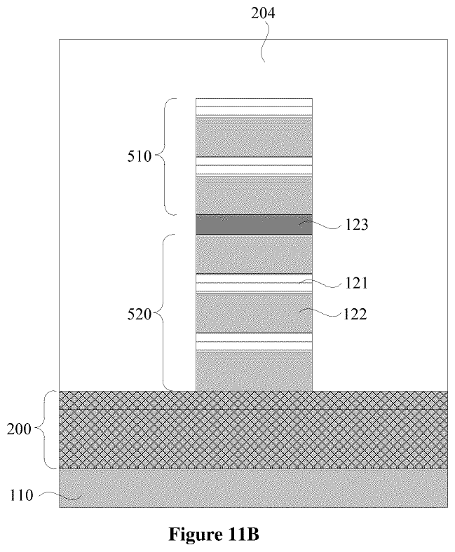

In S1061, a dummy gate 204 and second spacers 205 are formed, as shown in FIG. 11A and FIG. 11B. FIG. 11A and FIG. 11B are obtained by cross-sections of FIG. 1 in a XX direction and a YY direction respectively.

In an embodiment of the present disclosure, a dummy gate stack is formed at an exposed fin structure. The dummy gate stack has a multi-layer structure, which includes a gate insulating dielectric layer (not shown), the dummy gate 204 and a hard mask layer (not shown). The dummy gate stack may be formed by processes such as thermal oxidation, chemical vapor deposition, or sputtering. The dummy gate stack spans a stacked structure at an upper part of the fin structure, and a plurality of dummy gates are periodically distributed along a direction of a fin line. The dummy gate 204 may be made of polycrystalline silicon or amorphous silicon. The hard mask layer may be made of oxide, carbide, organic matter, etc.

In an embodiment of the present disclosure, second spacers 205 may be respectively provided at both sides of the dummy gate stack, and thicknesses of the second spacers 205 at both sides are the same. A material of the second spacers 205 may be dielectric material with isolation properties, such as silicon nitride or doped silicon oxide.

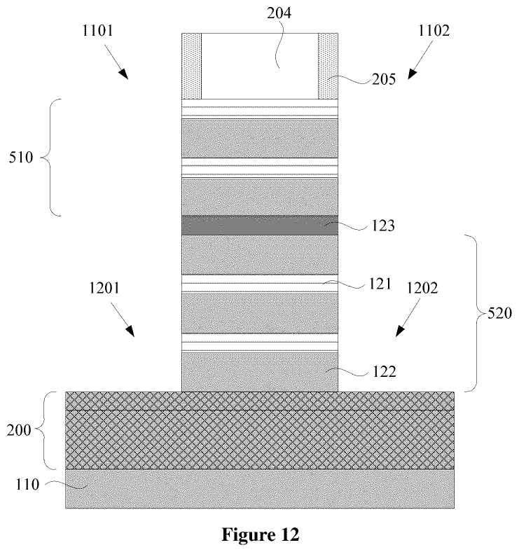

In S1062, the top structure, the buried oxide layer and the bottom structure are etched to form a top source region, a top drain region, a bottom source region and a bottom drain region, as shown in FIG. 12. FIG. 12 is obtained by a cross section of FIG. 1 in a XX direction.

In an embodiment of the present disclosure, after forming the dummy gate 204 and the second spacers 205, the dummy gate 204 and the second spacers 205 may be used as a mask, and source and drain etching is performed on the stacked structure through an etching process. Specifically, source and drain etching is performed on the top structure, the buried oxide layer 123 and the bottom structure, to form a top source region 1101, a top drain region 1102, a bottom source region 1201 and a bottom drain region 1202. A top channel region is between the top source region 1101 and the top drain region 1102, and a bottom channel region is between the bottom source region 1201 and the bottom drain region 1202. The top source region 1101, the top drain region 1102, the bottom source region 1201 and the bottom drain region 1202 no longer have a stacked structure after being etched, as shown in FIG. 12.

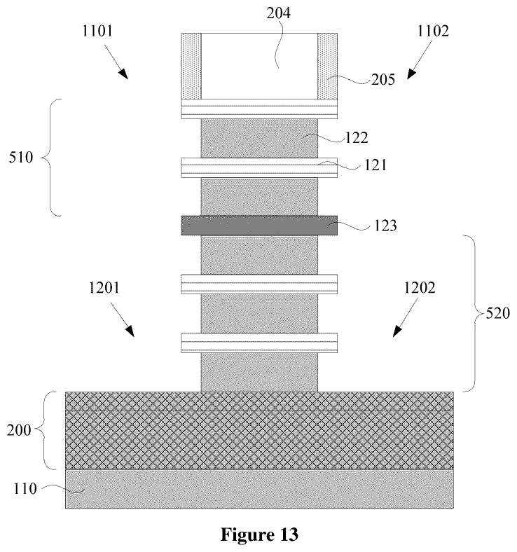

In S1063, a concave structure is formed, as shown in FIG. 13. FIG. 13 is obtained by a cross section of FIG. 1 in a XX direction.

In an embodiment of the present disclosure, the second semiconductor layers 122 located in the top structure 510 and the bottom structure 520 are laterally etched, that is, part of the second semiconductor layers 122 on a sidewall of the top structure 510 and a sidewall of the bottom structure 520 is removed through etching, and the first semiconductor layers 121 is not damaged. A missing part of the second semiconductor layers 122 compared to the first semiconductor layers 121 forms a concave structure. In other words, pull-back etching is performed to remove part of the second semiconductor layers 122 from the bottom source region 1201 and the bottom drain region 1202 toward the bottom channel region, and from the top source region 1101 and the top drain region 1102 toward the top channel region, as shown in FIG. 13.

While the second semiconductor layers 122 in the top structure 510 and the bottom structure 520 are selectively etched, the buried oxide layer 123 is not affected. A surface of the buried oxide layer 123, a surface of the first semiconductor layers 121 adjacent to the buried oxide layer 123, and a sidewall of the etched second semiconductor layers 122 in contact with the buried oxide layer 123 also form a concave structure.

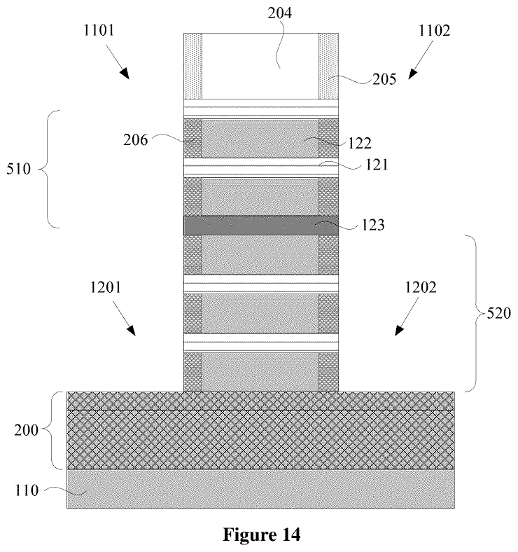

In S1064, an inner spacer is formed, as shown in FIG. 14. FIG. 14 is obtained by a cross section of FIG. 1 in a XX direction.

In an embodiment of the present disclosure, after etching on the second semiconductor layers 122 is finished, dielectric material is deposited at the bottom structure 520 located at the bottom channel region and the top structure 510 located at the top channel region, i.e., a periphery of the fin. The dielectric material is etched to form an inner spacer 206, and the inner spacer 206 is flush with the first semiconductor layers 121 in a direction perpendicular to a plane where the first substrate 110 is located. In other words, the concave structure formed by etching in S1063 is filled by the inner spacer 206, where the inner spacer 206 may be made of silicon nitride or silicon oxide.

When forming the inner spacer 206 in the concave structure, the inner spacer 206 is formed along both sides of the surface of the buried oxide layer 123 in a direction vertical to a surface of the bottom dielectric isolation layer 200. The inner spacer 206 and the buried oxide layer 123 constitute an intermediate dielectric layer, where the intermediate dielectric layer has an H-shaped structure.

Considering that two transistors of different doping types being stacked up and down need to be formed in the subsequent, it is to form sources and drains of the two transistors separately. A specific process is specifically described in the following.

In S106a, a bottom source and a bottom drain are formed at both sides of the bottom structure, and a top source and a top drain are formed at both sides of the top structure.

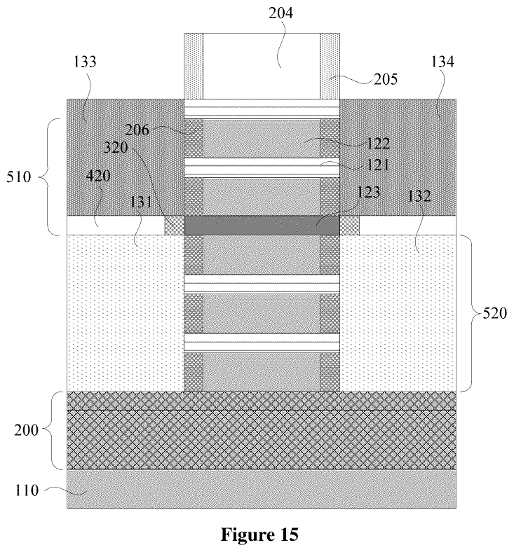

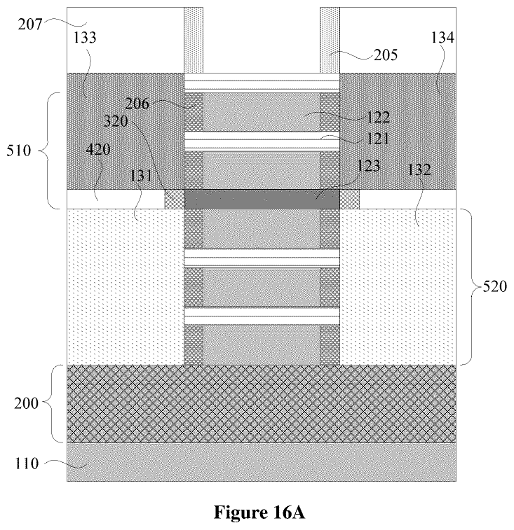

In an embodiment of the present disclosure, after etching the stacked structure to form the bottom source region 1201 and the bottom drain region 1202, a bottom source 131 and a bottom drain 132 may be formed in the bottom source region 1201 and the bottom drain region 1202 respectively, that is, the bottom source 131 and the bottom drain 132 are formed at both sides of the bottom structure 520, as shown in FIG. 15. FIG. 15 is obtained by a cross section of FIG. 1 in a XX direction. A surface of the bottom source 131 and the bottom drain 132 away from the first substrate 110 may be flush with a surface of the buried oxide layer 123 close to the first substrate 110.

In an embodiment, for different types of semiconductor devices, a material of a source and a material of a drain may be different. For a P-type semiconductor device, the source and the drain are made of boron-doped silicon germanium, i.e., SiGe:B; and for an N-type semiconductor device, the source and the drain are made of carbon-doped silicon, i.e., Si:C.

In an embodiment of the present disclosure, before forming the bottom source 131 and the bottom drain 132, target spacers 320 are formed by deposition and etching, and the target spacers 320 are at least located at sidewalls of the top channel structure, so as to realize isolation of the top channel structure, that is, the target spacers 320 are respectively provided at both sides of the top channel structure, and thicknesses of the target spacers 320 at both sides are the same. A material of the target spacers 320 may be dielectric material with isolation properties, such as silicon nitride or doped silicon oxide.

In an embodiment of the present disclosure, after forming the target spacers 320, a bottom source 131 and a bottom drain 132 may be formed in the bottom source region 1201 and the bottom drain region 1202 respectively, and then dielectric material is deposited and a planarization process is performed to form a first dielectric layer 420. The first dielectric layer 420 covers the top structure 510 and the target spacers 320. The first dielectric layer 420 may be etched back to the surface of the buried oxide layer 123 away from the first substrate 110, and the target spacers 320 may be etched back to the surface of the buried oxide layer 123 away from the first substrate 110, that is, the first dielectric layer 420 and the target spacers 320 are both etched to the buried oxide layer 123, thereby realizing isolation between a source and a drain of two upper and lower transistors.

In an embodiment of the present disclosure, after etching back the first dielectric layer 420 and the target spacers 320, the top source 133 and the top drain 134 may be further formed at the first dielectric layer 420 and the target spacers 320, that is, the top source 133 and the top drain 134 may be formed at both sides of the top structure 510, so as to form a source and a drain of a transistor located at an upper part of the two transistors stacked up and down, as shown in FIG. 15. The top source 133 and the top drain 134 may be specifically located at the first dielectric layer 420.

In S106b, the second semiconductor layers are removed to form a plurality of to-be-filled gaps, and the plurality of to-be-filled gaps are filled with a gate, where the plurality of first semiconductor layers surrounded by the gate constitute a channel structure, the channel structure includes a top channel structure and a bottom channel structure, and the top channel structure and the bottom channel structure are separated by the buried oxide layer.

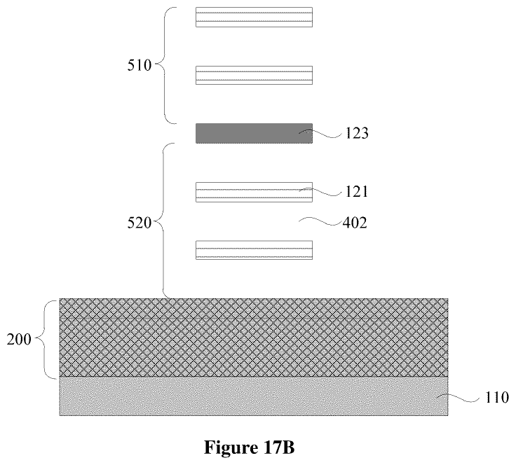

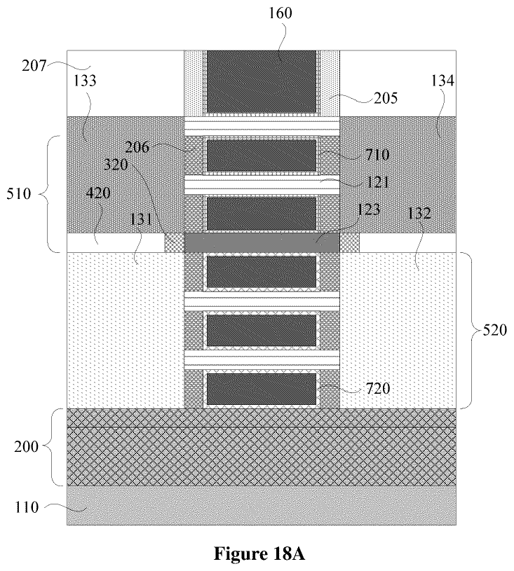

In an embodiment of the present disclosure, the second semiconductor layers 122 in the top channel region and the bottom channel region may be removed, that is, a nanosheet channel release procedure is performed, so as to form a plurality of to-be-filled gaps 402 between the first semiconductor layers 121, as shown in FIG. 17A and FIG. 17B. FIG. 17A and FIG. 17B are obtained by cross-sections of FIG. 1 in a XX direction and a YY direction respectively. Then, second-type work function layers 720 are formed in the plurality of to-be-filled gaps 402.

In an embodiment, the second semiconductor layers 122 in the stacked structure located in the top channel region and the bottom channel region may be selectively etched to perform nanosheet channel release. In other words, the stacked structure exposed by the fin is processed, each layer of the second semiconductor layers 122 is removed, that is, the second semiconductor layers 122 are sacrificial layers, and the nanosheets formed by the first semiconductor layers 121 are released.

In an embodiment of the present disclosure, before removing the second semiconductor layers 122 in the top channel region and the bottom channel region, the dummy gate 204 may be removed first. A specific process flow is as follows.

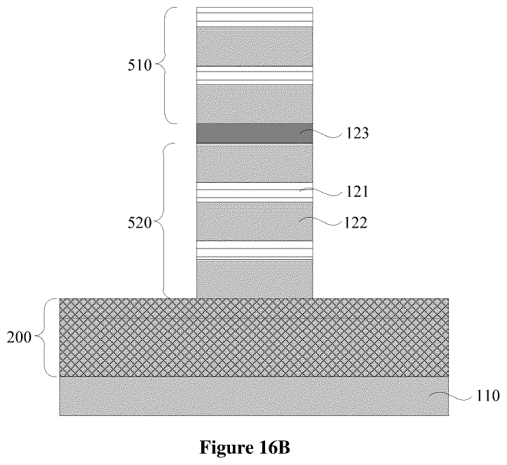

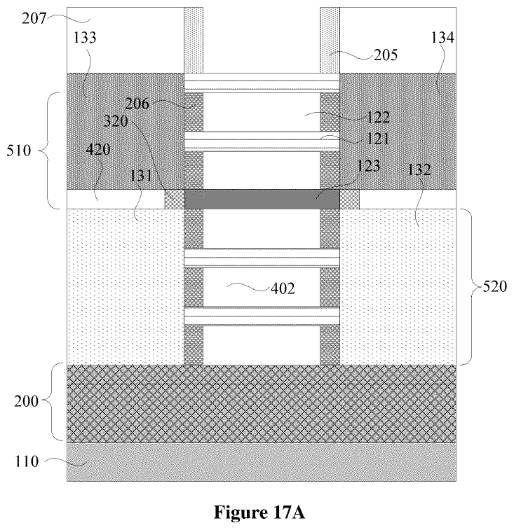

In S106c, the dummy gate is removed, referring to FIG. 16A and FIG. 16B. FIG. 16A and FIG. 16B are obtained by cross-sections of FIG. 1 in a XX direction and a YY direction respectively.

In an embodiment of the present disclosure, isolation layers 207 may be deposited at surfaces of the dummy gate 204, the top source 133 and the top drain 134 to prevent interconnect short circuit between the dummy gate 204 and the top source 133 or the top drain 1342 in subsequent steps, and a chemical mechanical polishing process is performed on the isolation layers 207 for planarization. Then, as shown in FIG. 16A and FIG. 16B, the dummy gate 204 formed of the polycrystalline silicon or amorphous silicon is etched or corroded by a selective etching or corrosion process, that is, the dummy gate 204 is removed.

In an embodiment of the present disclosure, after forming the plurality of to-be-filled gaps 402, an interface layer may be formed at a surface of the first semiconductor layers 121 and an interface between the interface layer and the first semiconductor layers 121 may be passivated. In an embodiment, the interface layer may be made of silicon oxide.

In an embodiment of the present disclosure, after forming the interface layer, a high-κ dielectric layer may be formed at a surface of the interface layer, and the high-κ dielectric layer surrounds the surface of the interface layer. In an embodiment, a material of the high-κ dielectric layer may be one or a combination of any of HfO₂, HfSiOₓ, HfON, HfSiON, HfAlOₓ, HfLaOₓ, Al₂O₃, ZrO₂, ZrSiOₓ, Ta₂O₅ or La₂O₃.

Considering that forming upper and lower transistors of different types needs to use an isolation layer to isolate different types of transistors and use different types of work function layers to realize different types of transistors, a specific process flow is described in the following.

In S106d, a second-type work function layer is formed in all the to-be-filled gaps.

In an embodiment of the present disclosure, the second-type work function layer 720 may be formed in all the to-be-filled gaps 402. Especially, the second-type work function layer 720 is formed in the plurality of to-be-filled gaps 402 of the bottom structure 520, and the second-type work function layer 720 surrounds the surface of the high-κ dielectric layer. In an embodiment, the second-type work function layer 720 is a P-type work function layer (P-WFL).

In S106e, the to-be-filled gaps in the bottom structure are filled with a protective layer.

In an embodiment of the present disclosure, isolation material may be deposited, and then the isolation material is etched back to a position of the buried oxide layer 123 to form the protective layer. In an embodiment, the isolation material may be etched back to a ½ position of the buried oxide layer 123. The protective layer fills the to-be-filled gaps 402 in the bottom structure 520.

In S106f, the second-type work function layer in the to-be-filled gaps of the top structure is removed, and the first-type work function layer is formed in the to-be-filled gaps of the top structure.

In an embodiment of the present disclosure, the second-type work function layer 720 in the to-be-filled gaps 402 of the top structure 510 is removed by using the protective layer as a mask, and the first-type work function layer 710 is formed in the to-be-filled gaps 402 of the top structure 510, so that the first-type work function layer 710 is formed at the top structure 510, and the second-type work function layer 720 is formed at the bottom structure 520. In an embodiment, the first-type work function layer 710 is an N-type work function layer (N-WFL). The second-type work function layer 720 in the to-be-filled gaps 402 of the top structure 510 may be removed by a corrosion process.

In S106g, the protective layer is removed.

In an embodiment of the present disclosure, after forming the first-type work function layer 710 and the second-type work function layer 720, the protective layer may be removed.

In practical applications, the protective layer may be removed first, and then the first-type work function layer 710 may be formed in all the to-be-filled gaps 402. That is, firstly, the second-type work function layer 720 may be formed in the to-be-filled gaps 402 of the bottom structure 520, and then the first-type work function layer 710 may be formed.

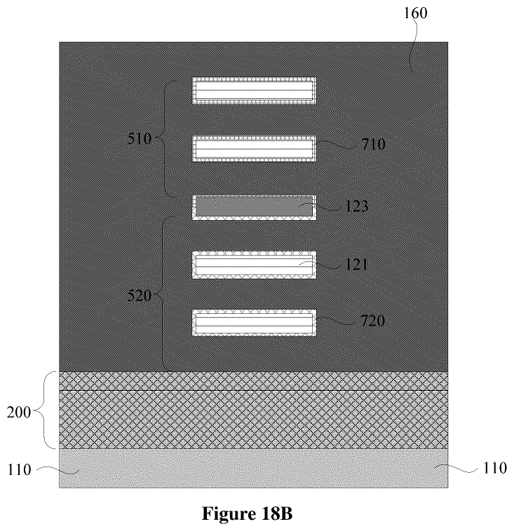

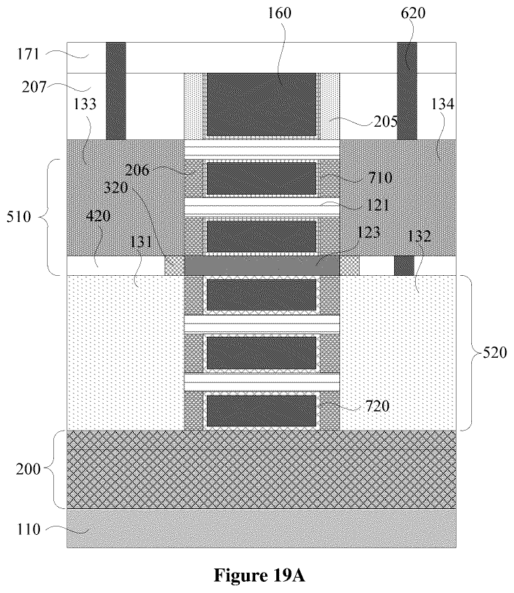

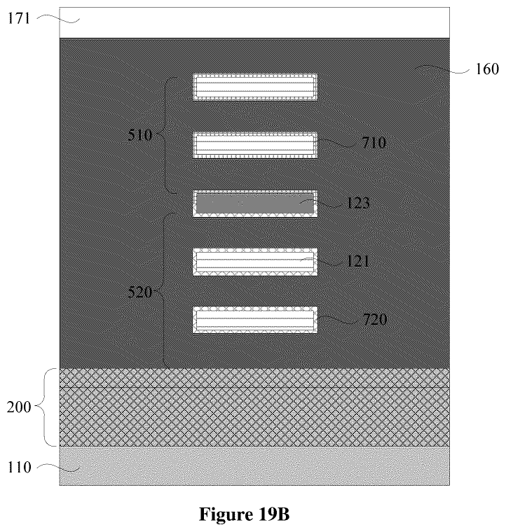

In an embodiment of the present disclosure, after nanosheet channel release is performed, the plurality of to-be-filled gaps 402 are provided between the plurality of first semiconductor layers 121, and the plurality of to-be-filled gaps 402 are filled with a gate 160. The gate 160 surrounds the first semiconductor layers 121, and forms a gate-all-around structure. In an embodiment, the gate 160 surrounds the first-type work function layer 710 and the second-type work function layer 720. A stack constituted by the plurality of first semiconductor layers 121 forms the top channel structure and the bottom channel structure, that is, a nanosheet channel of the field-effect transistor is formed, as shown in FIG. 18A and FIG. 18B. FIG. 18A and FIG. 18B are obtained by cross-sections of FIG. 1 in a XX direction and a YY direction respectively.

In practical applications, in addition to forming the gate 160 in the to-be-filled gaps 402, the gate 160 also covers space remained after removing the isolation layers 207 and the dummy gate 204. The gate 160 covering the isolation layers 207 may be chemically mechanically polished for planarization.

In an embodiment of the present disclosure, after forming the gate 160, dielectric deposition may be performed on a top of the field-effect transistor away from the first substrate 110 to form a top dielectric layer 171, a contact hole is etched in the top dielectric layer 171 to the surface of the top source 133 or the top drain 134, and metal material is deposited in the contact hole to form a contact electrode 620 of the top source 133 or the top drain 134, as shown in FIG. 19A and FIG. 19B. FIG. 19A and FIG. 19B are obtained by cross-sections of FIG. 1 in a XX direction and a YY direction respectively.

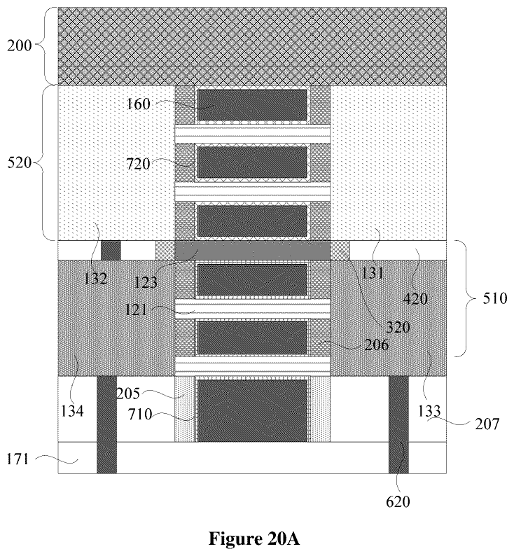

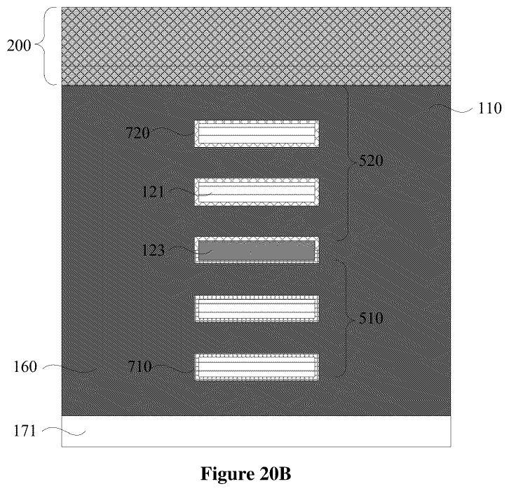

In an embodiment of the present disclosure, the first substrate 110 may also be removed, as shown in FIG. 20A and FIG. 20B. FIG. 20A and FIG. 20B are obtained by cross-sections of FIG. 1 in a XX direction and a YY direction respectively. The bottom dielectric isolation layer 200 is formed as a bottom substrate of the field-effect transistor, thereby overcoming a parasitic leakage problem of a ground plane heavily-doped well (GP Well) in a traditional bulk silicon field-effect transistor.

After removing the first substrate 110, dielectric deposition may be performed on a surface of the bottom dielectric isolation layer 200 away from the buried oxide layer 123 to form a bottom dielectric layer 172, a back contact hole is etched in the bottom dielectric layer 172 to a surface of the bottom source 131 or the bottom drain 132, and metal material is deposited in the back contact hole to form a back contact 610 of the bottom source 131 or the bottom drain 132, as shown in FIG. 2 and FIG. 3. That is, the bottom dielectric isolation layer 200 includes the back contact 610. The back contact 610 is connected to the bottom source 131 or the bottom drain 132, so as to realize electrical extraction of the field-effect transistor. The back contact 610 is made of metal material.

It can be seen that the, in the field-effect transistor provided by the embodiment of the present disclosure, a bottom dielectric isolation layer is formed by wafer bonding. The bottom dielectric isolation layer can reduce the volatility of a high fin etching process in the field-effect transistor, and optimize isolation between a back contact and an electrode in the field-effect transistor. A buried oxide layer in a SOI substrate or a GeOI substrate is used to form an intermediate dielectric insulation layer of the field-effect transistor, thereby effectively reducing the complexity of formation process of the intermediate dielectric insulation layer and a Ge diffusion of a heavily doped SiGe layer. In addition, this manufacture method is compatible with manufacture technologies of devices and unit circuits in mainstream CFET integration processes.

The embodiments in this specification are described in a progressive manner, the same or similar parts between the embodiments may be referred to each other, and each embodiment focuses on the differences from other embodiments. In particular, since the method embodiment is basically similar to the structural embodiment, the description thereof is relatively concise, and for relevant parts reference may be made to the part in description of the structural embodiment. The structural embodiment described above is only illustrative, and those of ordinary skill in the art may understand and implement it without any creative effort.

The above are only preferred implementations of the present disclosure. Although the present disclosure is disclosed by referring to preferred embodiments, it is not intended to limit the present disclosure. Numerous modifications, variations and equivalent alternatives can be made by those skilled in the art based on the above disclosed method and technical contents without departing from the scope of the technical solutions. Therefore, any simple amendment, equivalent change or modification made to the above embodiments based on the technical essence of the present disclosure without departing from the content of the technical solutions of the present disclosure still falls within the protection scope of the technical solutions of the present disclosure.

1. A field-effect transistor comprising:
a bottom dielectric isolation layer, wherein the bottom dielectric isolation layer comprises a first bonding layer and a second bonding layer;
a top source, a top drain, a top channel structure, a bottom source, a bottom drain and a bottom channel structure provided on the bottom dielectric isolation layer, wherein the top channel structure and the bottom channel structure overlap in a direction perpendicular to a plane where the bottom dielectric isolation layer is located, the top channel structure and the bottom channel structure are isolated by an intermediate dielectric layer, the top channel structure is located between the top source and the top drain, the bottom channel structure is located between the bottom source and the bottom drain, and the top channel structure and the bottom channel structure comprise a stack formed by a plurality of nanosheets; and
a gate, wherein the gate surrounds the nanosheets.

2. The field-effect transistor according to claim 1, wherein a thickness of the first bonding layer is greater than a thickness of the second bonding layer, and the thickness of the first bonding layer is greater than a thickness of the intermediate dielectric layer.

3. The field-effect transistor according to claim 2, wherein the thickness of the first bonding layer and the thickness of the second bonding layer range from 1 nm to 1000 nm.

4. The field-effect transistor according to claim 1, wherein the first bonding layer or the second bonding layer is made of one or more of SiO2, SiNx, SiNO, SiCO, SiCNO and SiCN.

5. The field-effect transistor according to claim 1, wherein a thickness of the intermediate dielectric layer ranges from 1 nm to 100 nm.

6. The field-effect transistor according to claim 1, wherein conductivity types of the top channel structure and the bottom channel structure are N-type and P-type respectively; or P-type and N-type respectively.

7. The field-effect transistor according to claim 1, wherein the intermediate dielectric layer comprises a first portion located at a center and a second portion located at both sides of the first portion, wherein the second portion extends along both sides of a surface of the first portion in a direction perpendicular to a surface of the bottom dielectric isolation layer, and a thickness of the second portion is greater than a thickness of the first portion.

8. The field-effect transistor according to claim 7, wherein a contact interface is comprised between the first portion and the second portion.

9. A method for manufacturing a field-effect transistor, comprising:
providing a first substrate, and forming a first bonding layer at the first substrate;
providing a semiconductor-on-insulator substrate, wherein the semiconductor-on-insulator substrate comprises a bottom semiconductor substrate, a buried oxide layer and a top semiconductor substrate that are stacked in layers, a first stacked structure and a second bonding layer are formed at the semiconductor-on-insulator substrate, and the first stacked structure is obtained by alternately stacking a plurality of first semiconductor layers and a plurality of second semiconductor layers;
bonding the first substrate and the semiconductor-on-insulator substrate in a direction where the second bonding layer faces the first bonding layer;
forming a second stacked structure at the bottom semiconductor substrate, wherein the second stacked structure is obtained by alternately stacking a plurality of first semiconductor layers and a plurality of second semiconductor layers; and
processing the first stacked structure and the second stacked structure to form the field-effect transistor.

10. The method according to claim 9, wherein processing the first stacked structure and the second stacked structure to form the field-effect transistor comprises:
processing the first stacked structure and the second stacked structure to form a nanosheet stacked structure, wherein the nanosheet stacked structure comprises a bottom structure located below the buried oxide layer and a top structure located above the buried oxide layer;
forming a bottom source and a bottom drain at both sides of the bottom structure, and forming a top source and a top drain at both sides of the top structure; and
removing the second semiconductor layers to form a plurality of to-be-filled gaps, and filling the plurality of to-be-filled gaps with a gate, wherein the plurality of first semiconductor layers surrounded by the gate constitute a channel structure, the channel structure comprises a top channel structure and a bottom channel structure, and the top channel structure and the bottom channel structure are separated by the buried oxide layer.

11. The method according to claim 10, wherein before forming the bottom source and the bottom drain at both sides of the bottom structure, the method further comprises:
laterally etching the second semiconductor layers located in the top structure and the bottom structure to form a concave structure; and
forming an inner spacer in the concave structure.

12. The method according to claim 11, wherein forming the inner spacer in the concave structure comprises:
forming an inner spacer along both sides of a surface of the buried oxide layer in a direction perpendicular to a surface of the bottom dielectric isolation layer, wherein the inner spacer and the buried oxide layer constitute an intermediate dielectric layer.

13. The method according to claim 10, wherein after forming the bottom source and the bottom drain at both sides of the bottom structure and before forming the top source and the top drain at both sides of the top structure, the method further comprises:
forming a first dielectric layer between the bottom source and the bottom drain at both sides of the bottom structure and between the top source and the top drain at both sides of the top structure.

14. The method according to claim 10, wherein before filling the plurality of to-be-filled gaps with the gate, the method further comprises:
forming a second work function layer in the plurality of to-be-filled gaps of the bottom structure; and
forming a first work function layer in the plurality of to-be-filled gaps of the top structure.

15. The method according to claim 9, wherein before forming the second stacked structure at the bottom semiconductor substrate, the method further comprises:
thinning a thickness of the bottom semiconductor substrate to a thickness of the first semiconductor layers or a thickness of the second semiconductor layers.

16. The method according to claim 9, wherein a first substrate is a silicon substrate, a germanium substrate or a germanium-silicon substrate, and a semiconductor-on-insulator substrate is a silicon-on-insulator substrate, a germanium-on-insulator substrate or a germanium-silicon-on-insulator substrate.
